(19) United States
(12) Patent Application Publication
(10) Pub. No.: US 2026/0328732 A1
(43) Pub. Date: Oct. 22, 2026

(54) ELECTRONIC SLIDE RAIL MECHANISM, GAIN COMPENSATION CONTROL SYSTEM, AND ULTRASONIC IMAGING APPARATUS

(71) Applicant: GE Precision Healthcare LLC, Waukesha, WI (US)

(72) Inventors: Hua Zhang, Wuxi (CN); Xiaoren Wang, Wuxi (CN); Linbo Yang, Wuxi (CN); Xudong Wu, Wuxi (CN)

(21) Appl. No.: 19/651,019

(22) Filed: Apr. 17, 2026

(30) Foreign Application Priority Data
Apr. 17, 2025 (CN) 202510486523.X

(51) Int. Cl. G01N 29/40; H03G 3/14; H05K 5/03; H05K 5/06

(52) U.S. Cl. CPC G01N 29/40; H03G 3/14; H05K 5/03; H05K 5/061

(57) ABSTRACT

A gain compensation control system for an ultrasonic system including an electronic slide rail mechanism that includes: a separator, defining a separation region, a first side and a second side of the separator being completely separated in a range of the separation region; a driving slider, located at the first side of the separator, the driving slider being capable of reciprocating within the range of the separation region; a driven slider, located at the second side of the separator and disposed corresponding to the driving slider; a transmission assembly having a transmission coupling with the driving slider and the driven slider, wherein the driving slider is configured to drive, via the transmission assembly, the corresponding driven slider to reciprocate in the range of the separation region; and a circuit assembly, located at the second side of the separator, the circuit assembly comprising an electronic device, the electronic device being located in the range of the separation region.

### CROSS-REFERENCE TO RELATED APPLICATION

This application claims priority to Chinese Patent Application No. 202510486523.X, which was file on Apr. 17, 2025 at the Chinese Patent Office. The entire contents of the above-listed application are incorporated by reference herein in their entirety.

### TECHNICAL FIELD

The present application relates to the field of medical equipment, and more specifically, to an electronic slide rail mechanism, a gain compensation control system including the electronic slide rail mechanism, and an ultrasonic imaging apparatus including the gain compensation control system.

### BACKGROUND

With the rapid development of medical technologies, the technology of imaging using ultrasonic waves (ultrasonic imaging technology), as a non-invasive, real-time and safe medical diagnosis means, is widely used in the field of clinical medicine. Ultrasonic imaging technology has an irreplaceable status, especially in cardiovascular, obstetric, abdominal and muscular examinations. Further, a principle of ultrasonic imaging technology is that when an ultrasonic wave is propagated in biological tissue, reflection, scattering, and attenuation occur due to a difference in acoustic impedance of different tissue, and a received echo signal is converted into a visual grayscale or color image after being processed, to provide a doctor with visual information of an anatomical structure and a pathological change.

For an ultrasonic imaging apparatus using the described ultrasonic imaging technology, energy of an ultrasonic wave is attenuated due to effects such as absorption and scattering during propagation in biological tissue, and degree of attenuation is positively correlated with a propagation depth. If compensation is not performed, an echo signal generated by shallow tissue may be saturated due to excessively high signal strength, and an echo signal generated by deep tissue may be difficult to distinguish due to excessively low signal strength. Therefore, optimization of signal processing is crucial. Two technologies, namely, time gain compensation (TGC, for short) and lateral gain compensation (LGC, for short), are key means for improving image quality. Specifically, time gain compensation achieves image uniformity by means of dynamically adjusting gains of echo signals at different depths, to ensure accuracy and consistency of diagnosis. Lateral gain compensation, by adjusting gain distribution on a lateral scanning line, compensates for a signal difference caused by sound beam spread or uneven contact of a probe.

Existing conventional time gain compensation control systems and lateral gain compensation control systems usually use a sliding push-pull mechanical structure in conjunction with an electronic device to achieve gain compensation, and an operator can adjust a gain curve by means of the sliding push-pull mechanical structure via a potentiometer or an encoder. An operation panel of the sliding push-pull mechanical structure is usually provided with a sliding adjustment button, and a user can manually adjust a gain value of each depth interval based on real-time image feedback. Such a sliding push-pull mechanical structure is widely used due to intuitive operation and low costs. However, the openness of such a sliding push-pull mechanical structure causes the electronic device used in conjunction with the sliding push-pull mechanical structure to be directly exposed to an external environment, and once a liquid such as water or disinfectant is sprayed onto the sliding push-pull mechanical structure, failure of the electronic device may be caused. Consequently, the gain compensation control system cannot work normally.

### SUMMARY

Based on the described problem in the prior art, an object of the present application is to provide an electronic slide rail mechanism, which can effectively reduce or even completely eliminate the probability that liquid such as water and disinfectant flows to a region in which an electronic device is located, thereby achieving liquid-proof functionality with a relatively simple configuration.

Another object of the present application is to provide a gain compensation control system comprising the described electronic slide rail mechanism, which can effectively reduce or even completely eliminate the probability of a failure of the control system caused by liquid flowing to an electronic device of the electronic slide rail mechanism while controlling gain compensation for ultrasonic imaging.

Still another object of the present application is to provide an ultrasonic imaging apparatus comprising the described gain compensation control system, which can effectively reduce or even completely eliminate the probability of a failure of the ultrasonic imaging apparatus caused by liquid flowing to an electronic device of an electronic slide rail mechanism while improving quality of ultrasonic imaging through the gain compensation control system.

To achieve the foregoing objects, the implementations of the present application may adopt the following technical solutions.

An embodiment of the present application provides the following electronic slide rail mechanism, comprising:

A separator, defining a separation region, a first side and a second side of the separator being completely separated in a range of the separation region;

A driving slider, located at the first side of the separator, the driving slider being capable of reciprocating within the range of the separation region;

A driven slider, located at the second side of the separator and disposed corresponding to the driving slider;

A transmission assembly, the transmission assembly having a transmission coupling with the driving slider and the driven slider, so that the driving slider is capable of driving, via the transmission assembly, the corresponding driven slider to reciprocate in the range of the separation region; and

A circuit assembly, located at the second side of the separator, the circuit assembly comprising an electronic device, the electronic device being located in the range of the separation region, and movement of the driven slider being capable of causing a change in an electrical characteristic of the electronic device.

In an optional solution, the separator comprises a partition portion and a side wall portion, and the side wall portion extends from the partition portion toward the first side, so that the partition portion and the side wall portion surroundingly form the separation region.

In another optional solution, a top cover and a sealing member are further comprised, the top cover is mutually fastened with the separator and located at the first side of the separator, the top cover being formed with a slideway corresponding to the driving slider, and the driving slider being disposed in the corresponding slideway and exposed from the top cover, and

The top cover abuts against the side wall portion via the sealing member, so that an accommodating cavity is formed at the separation region, and the accommodating cavity is only capable of communicating with the outside via the slideway.

In another optional solution, the transmission assembly comprises a first transmission member and a second transmission member, the first transmission member being connected to the driving slider, the second transmission member being connected to the driven slider, and the first transmission member having a transmission coupling with the second transmission member through the side wall portion.

In another optional solution, a sealing member is further comprised, and the sealing member is disposed between the first transmission member and the side wall portion.

In another optional solution, the first transmission member is disposed separated from the separator in the range of the separation region.

In another optional solution, the first transmission member comprises an extension portion passing through the side wall portion, and the extension portion is fixedly connected to the second transmission member.

In another optional solution, each transmission assembly comprises two first transmission members located at two sides of the driving slider, each first transmission member comprising an extension portion passing through the side wall portion, and each extension portion being opposite to a corresponding end portion of a second transmission member, so that the driving slider abuts against the corresponding end portion of the second transmission member via the extension portion to drive the driven slider.

In another optional solution, the first transmission member is formed as a transmission rod extending linearly, the two first transmission members are coaxially arranged,

A first end portion of the first transmission member is inserted into the driving slider, a second end portion of the first transmission member is formed as the extension portion, and there is a gap between at least one extension portion and a corresponding end portion of the second transmission member.

In another optional solution, the first transmission member and the second transmission member are each a flexible connection member, the paired first transmission member and second transmission member are directly connected to each other to form a transmission connection member, and two side portions of the driving slider are connected to two side portions of the driven slider, respectively, by means of two transmission connection members,

The electronic slide rail mechanism further comprises a pulley, the pulley is fixed relative to the separator, and each transmission connection member is wound around a corresponding pulley and is tensioned and supported by the pulley.

In another optional solution, the circuit assembly has a slide rail, and the driven slider is mounted on the slide rail, so that the driven slider is capable of reciprocating on the slide rail to cause the change in the electrical characteristic of the electronic device.

In another optional solution, the electrical characteristic is resistance or capacitance.

In another optional solution, the circuit assembly further comprises a circuit board, the electronic device is mounted on the circuit board, and the circuit board and the separator are fastened to each other.

In another optional solution, a plurality of driving sliders arranged separate from each other and a plurality of driven sliders arranged separate from each other are comprised, one driving slider having a corresponding transmission coupling with one driven slider, and all the driving sliders and all the driven sliders reciprocating in parallel with each other.

The present application further provides the following gain compensation control system, used for an ultrasonic imaging apparatus. The gain compensation control system comprises the electronic slide rail mechanism according to any one of the foregoing technical solutions.

In an optional solution, the gain compensation control system is a time gain compensation control system or a lateral gain compensation control system.

The present application further provides the following ultrasonic imaging apparatus, comprising the gain compensation control system according to any one of the described technical solutions.

### BRIEF DESCRIPTION OF THE DRAWINGS

FIG. 1 is a schematic top view showing an electronic slide rail mechanism according to an embodiment of the present application.

FIG. 2 is a schematic perspective view showing the electronic slide rail mechanism in FIG. 1, in which a partial structure is in an exploded state.

FIG. 3 is a schematic cross-sectional view showing the electronic slide rail mechanism taken along the line S1-S1 in FIG. 1.

FIG. 4 is a schematic top view showing a partial structure of the electronic slide rail mechanism in FIG. 1.

FIG. 5 is a schematic perspective view showing the structure in FIG. 4.

FIG. 6 is a schematic cross-sectional view showing the electronic slide rail mechanism taken along the line S2-S2 in FIG. 4.

FIG. 7 is a schematic top view showing a partial structure of the electronic slide rail mechanism in FIG. 1.

FIG. 8 is a schematic perspective view showing the structure in FIG. 7.

FIG. 9 is a schematic top view showing a combination of a separator and a sealing member of the electronic slide rail mechanism in FIG. 1.

FIG. 10 is a schematic perspective view showing the combination in FIG. 9.

FIG. 11 is a schematic top view showing an electronic slide rail mechanism according to an embodiment of the present application.

FIG. 12 is a schematic cross-sectional view showing the electronic slide rail mechanism taken along the line S3-S3 in FIG. 1.

FIG. 13 is a schematic perspective view showing a partial structure of an ultrasonic imaging apparatus according to an embodiment of the present application.

### DETAILED DESCRIPTION

Embodiments of the present application are described below with reference to the accompanying drawings. For ease of understanding, elements shown in the drawings may include elements whose dimensions, scales and the like differ from actual dimensions, scales, and the like. Additionally, in order to provide a concise description in the specific description process of the embodiments, not all features of the embodiments are described in detail. For those of ordinary skill in the art related to the disclosure of the present application, some supplements and refinements, as well as design, manufacture, or production changes made on the basis of the technical content disclosed in the present application are common technical means and still fall within the scope of the present application, and should not be construed as the disclosure of the present application being insufficient.

Unless defined otherwise, the technical terms or scientific terms used in the claims and the description should have the usual meanings that are understood by those skilled in the art to which the present application belongs. Terms such as “first”, “second”, and similar terms used in the description and claims of the present application do not denote any order, quantity, or importance, but are only intended to distinguish different constituents. The word “include,” “comprise,” or a similar word is intended to mean that a component or an object that appears before “include” or “comprise” encompasses a component or an object and equivalent components that are listed after “include” or “comprise,” and does not exclude other components or objects. The terms “connect” or “link” and similar words are not limited to physical or mechanical connections, and are not limited to direct or indirect connections.

In the present application, the use of the expression “substantially” intends to mean that a condition defined by such expression is satisfied within a reasonable error range recognized by those skilled in the art, and the expression has a similar meaning when it is used in the following description.

In the present application, “transmission coupling” between two components means that the two components are connected in a manner capable of transmitting a driving force, including direct and indirect connections.

In the present application, a “first direction” refers to the height direction of an electronic slide rail mechanism (particularly a separator) according to the present application, a “second direction” refers to the length direction of the electronic slide rail mechanism (particularly the separator) according to the present application, and a “third direction” refers to the width direction of the electronic slide rail mechanism (particularly the separator) according to the present application. Further, in the first direction, there are a first side and a second side. When the electronic slide rail mechanism is mounted in place and the first direction is consistent with a vertical direction, the first side is an upper side in the vertical direction and the second side is a lower side in the vertical direction.

In the present application, a “separation region” refers to a region as follows: in a range of the separation region, the separator is not formed having a passage such as a through hole that places the two sides of the separator in communication, and thus the two sides of the separator are completely separated in the range of the separation region. “In the range of the separation region” refers to being in a range covered by a projection of the separation region on any imaginary plane in the first direction perpendicular to the imaginary plane, the imaginary plane including the second direction and the third direction. With such a structure, the first side and the second side of the separator are completely separated in the range of the separation region.

An electronic slide rail mechanism according to a first embodiment of the present application is specifically described below with reference to the accompanying drawings.

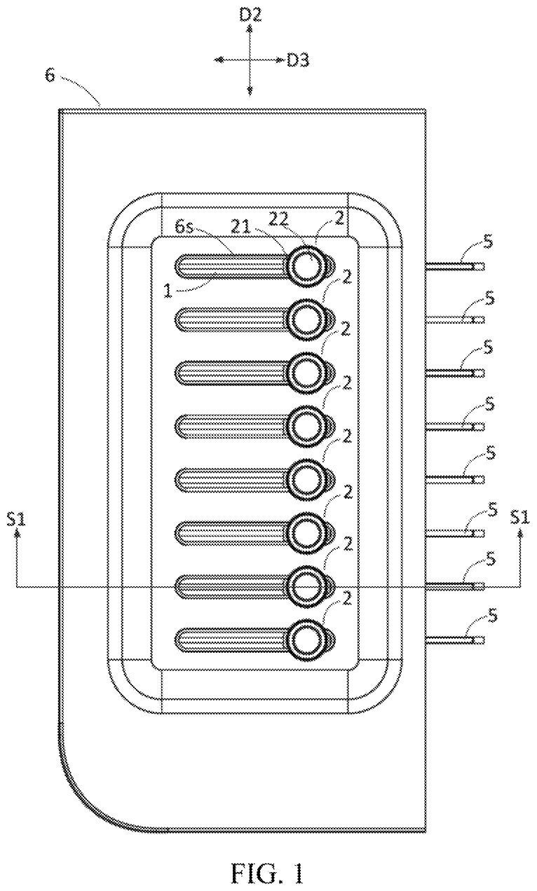

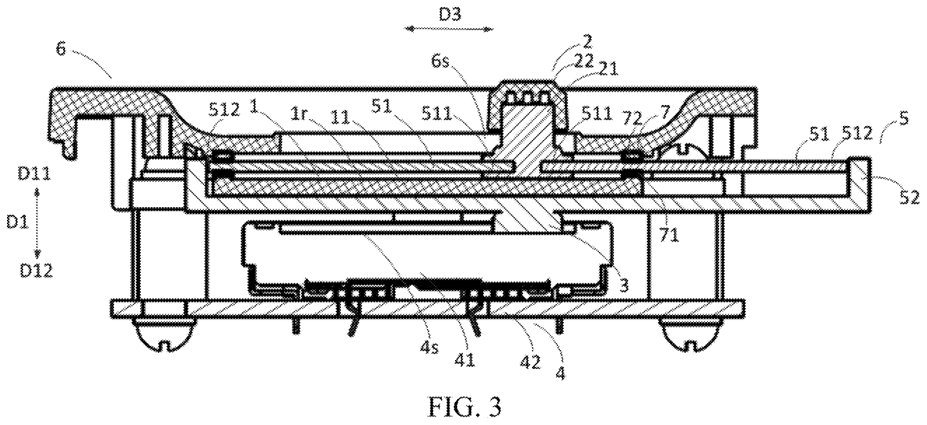

The electronic slide rail mechanism according to the present application may be typically used in a gain compensation control system of an ultrasonic imaging apparatus. As shown in FIG. 1 to FIG. 3, the electronic slide rail mechanism according to the first embodiment of the present application includes a separator 1, a driving slider 2, a driven slider 3, a circuit assembly 4 and a transmission assembly 5, which are assembled together. In this embodiment, the separator 1 defines a separation region 1r. Referring to FIG. 3, a first side D11 and a second side D12 of the separator 1 are completely separated in a range of the separation region 1r. The driving slider 2 is located at the first side D11 of the separator 1, and the driving slider 2 can reciprocate in the range of the separation region 1r. The driven slider 3 is located at the second side D12 of the separator 1 and disposed corresponding to the driving slider 2. The transmission assembly 5 has a transmission coupling with both the driving slider 2 and the driven slider 3, so that the driving slider 2 can, via the transmission assembly 5, drive the corresponding driven slider 3 to reciprocate in the range of the separation region 1r. In addition, the circuit assembly 4 is also located at the second side D12 of the separator. The circuit assembly 4 includes an electronic device 41. The electronic device 41 is located in the range of the separation region 1r. Thus, the driven slider 3 can cause a change in an electrical characteristic (for example, capacitance or resistance) of the electronic device.

It may be understood that the figures show specific shapes and structures of the separator 1, the driving slider 2, the driven slider 3, the circuit assembly 4 and the transmission assembly 5, but this embodiment is not actually limited to the specific shapes and structures shown in the figures. These components can have various appropriate shapes and structures as required as long as the components can have the functions described above.

According to the described solution, the driving slider 2, the driven slider 3, and the transmission assembly 5 form a mechanical structure, and linkage of the mechanical structure can smoothly cause the change in the electrical characteristic of the electronic device of the circuit assembly 4. With such a basic structure, the first side D11 and the second side D12 of the separation region 1r of the separator 1 are completely spaced apart by using the separator. Even if a liquid such as water or disinfectant flows to the first side D11 of the separation region 1r of the separator 1, the liquid is blocked by the separator 1 and cannot flow to the second side D12 of the separation region 1r; that is, it does not flow to a region in which the circuit assembly 4 is located. Therefore, the probability that the circuit assembly 4 encounters a failure because the liquid flowing to the first side D11 of the separation region 1r further flows to the second side D12 of the separation region 1r can be greatly reduced or even completely avoided. Thus, the electronic slide rail mechanism implements liquid-proof functionality with a relatively simple configuration. In addition, a modular configuration of the entire electronic slide rail mechanism can be implemented by assembling the described components together, which facilitates transportation and mounting.

An electronic slide rail mechanism according to a second embodiment of the present application is described below.

Still as shown in FIG. 1 to FIG. 3, the electronic slide rail mechanism according to the second embodiment of the present application includes a separator 1, a driving slider 2, a driven slider 3, a circuit assembly 4, a transmission assembly 5, a top cover 6 and a sealing member 7, which are assembled together.

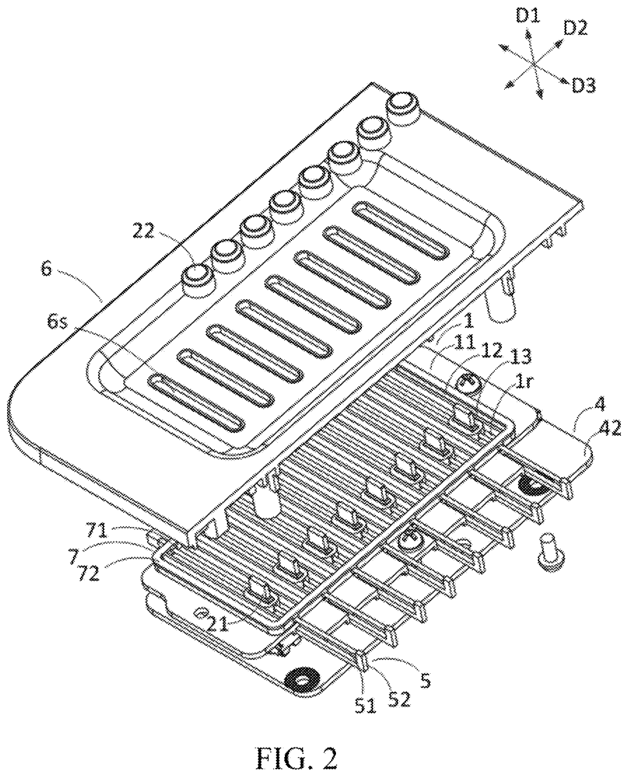

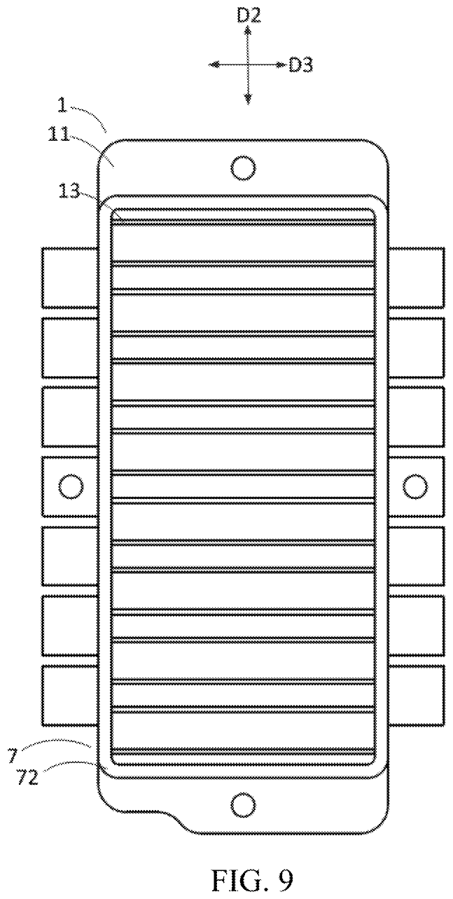

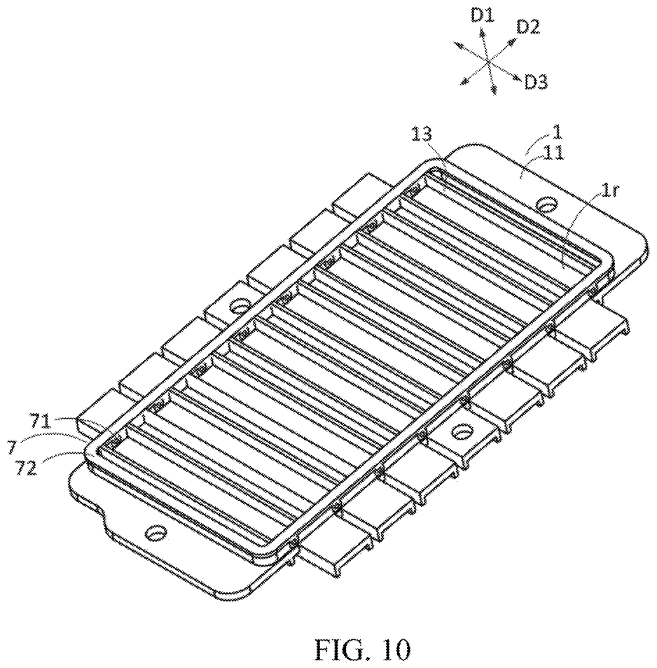

In this embodiment, the separator 1 may be integrally formed using, for example, rigid plastic. As shown in FIG. 2 to FIG. 5, FIG. 9 and FIG. 10, the separator 1 is formed into a plate-like configuration as a whole, and the thickness direction, the length direction and the width direction of the separator 1 are a first direction D1, a second direction D2 and a third direction D3, respectively. Specifically, the separator 1 includes a partition portion 11, a side wall portion 12 and a partition wall portion 13, which are integrally formed. Thus, the partition portion 11, the side wall portion 12, and the partition wall portion 13 are fastened to each other.

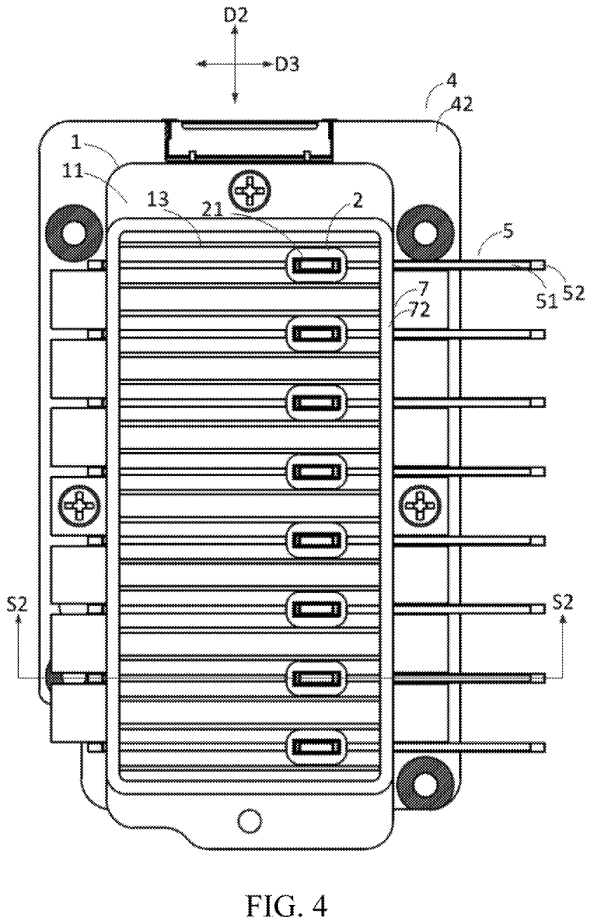

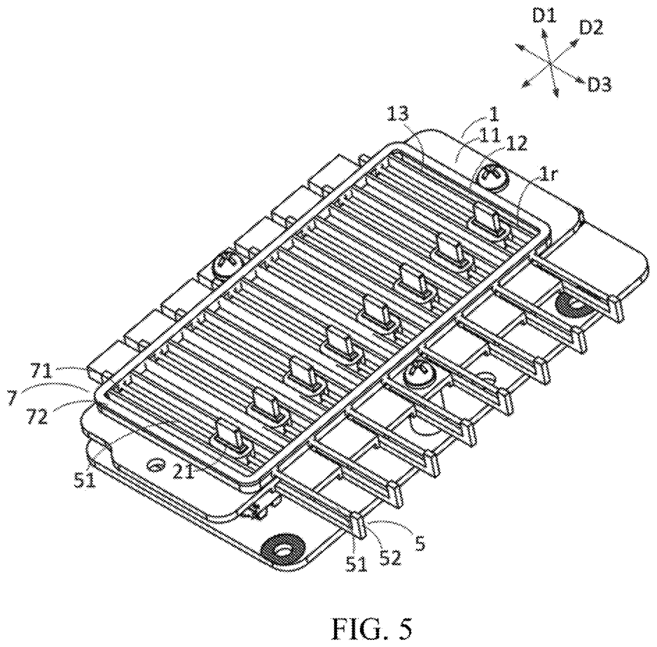

As shown in FIG. 4, FIG. 5, FIG. 9 and FIG. 10, the partition portion 11 is formed into a flat plate structure. In the first direction D1, a plurality of side wall portions 12 are positioned on the first side D11 of the partition portion 11, and the plurality of side wall portions 12 extend from the partition portion 11 toward the first side D11, so that the plurality of side wall portions 12 stand upright with respect to the partition portion 11. These side wall portions 12 are connected end to end, thereby defining an approximately rectangular space inside the side wall portions. In this way, in this embodiment, the separation region 1r is formed through surrounding between the partition portion 11 and the side wall portion 12. In addition, a plurality of partition wall portions 13 extend from the partition portion 11 toward the first side D11, so that the plurality of partition wall portions 13 stand upright with respect to the partition portion 11. These partition wall portions 13 further extend in parallel with each other along the third direction D3, and two ends of each partition wall portion 13 are each connected to side wall portions 12 opposite to each other, so that the separation region 1r is divided into a plurality of sub-regions by the plurality of partition wall portions 13. Some of these sub-regions are used for mounting the driving slider 2, and limiting the driving slider 2 during reciprocating sliding of the driving slider 2 along the third direction D3. In this way, even if a liquid such as water or disinfectant flows into a sub-region via the below-described slideway 6s of the top cover 6, it is difficult for the liquid to enter another sub-region due to the presence of the partition wall portions 13. Therefore, constrained flowing of the liquid not only reduces adverse impact caused by the liquid flowing into the electronic slide rail mechanism, but also facilitates cleaning of the separator 1 when the liquid flows into the separation region 1r.

It may be understood that the present application limits neither a material of the separator 1 nor a specific configuration of the separator 1. As long as the separator 1 can have sufficient mechanical strength and define a sufficiently large separation region 1r, the separator 1 can adopt different materials and different configurations as required.

In this embodiment, the driving slider 2 may adopt a split configuration, and the parts may be assembled together after being made of, for example, rigid plastic. As shown in FIG. 1 to FIG. 6, a plurality of driving sliders 2 are all located at the first side D11 of the separator 1, and these driving sliders 2 are arranged side by side and spaced apart from each other in the first direction D1. Under the operation of an operator, all of these driving sliders 2 can slide in a reciprocating manner along the third direction D3. Each driving slider 2 can reciprocate in the range of the separation region 1r, that is, a sliding range of the driving slider 2 does not exceed the separation region 1r. Specifically, the driving slider 2 includes a slider body 21 and a slider cap 22, which are assembled and fastened together. As shown in FIG. 2 to FIG. 6, each slider body 21 includes a lower side portion having a larger cross-section and an upper side portion having a smaller cross-section, and the lower side portion and the upper side portion are fastened to each other. The lower side portion of each slider body 21 is mounted between adjacent partition wall portions 13. When the partition wall portion 13 provides position limiting, the slider body 21 can slide in a reciprocating manner in the range of the separation region 1r along the third direction D3. The upper side portion of each slider body 21 is inserted into the slideway 6s of the top cover 6, and a part of the upper side portion is exposed with respect to the top cover 6. Further, the slider cap 22 is mounted, for example, in an interference fit manner, in the part of the upper side portion exposed with respect to the top cover 6. The slider cap 22 facilitates the operator holding the driving slider 2 for reciprocating sliding.

It may be understood that the present application limits neither a material nor a specific configuration of the driving slider 2. As long as the driving slider 2 can be operated by the operator to slide in a reciprocating manner in the range of the separation region 1r along the third direction D3, the driving slider 2 can adopt different materials and different configurations as required.

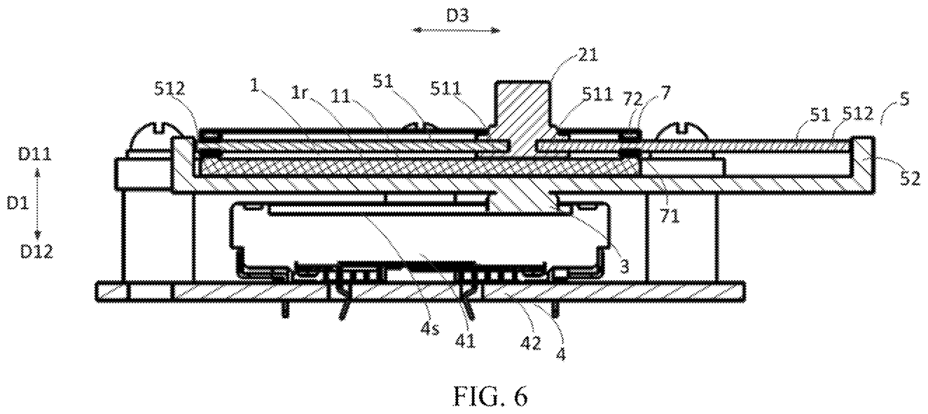

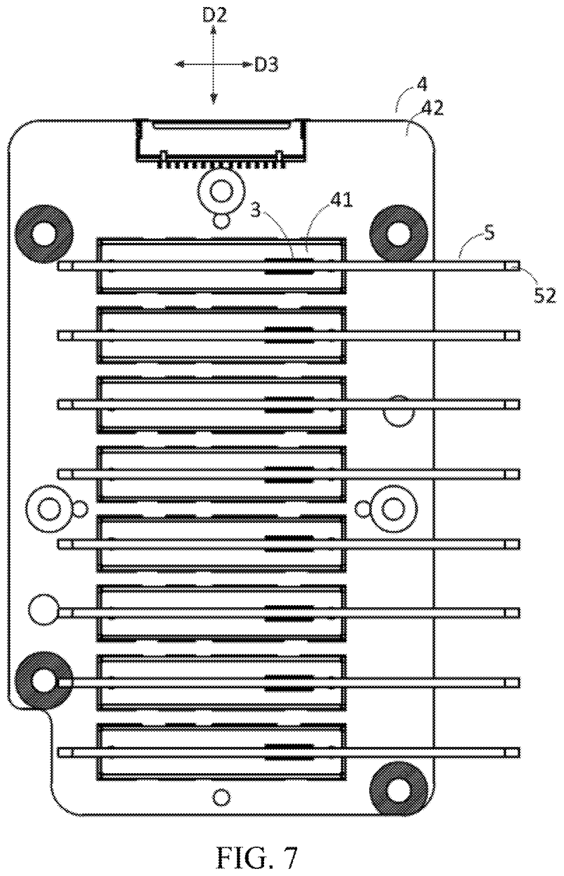

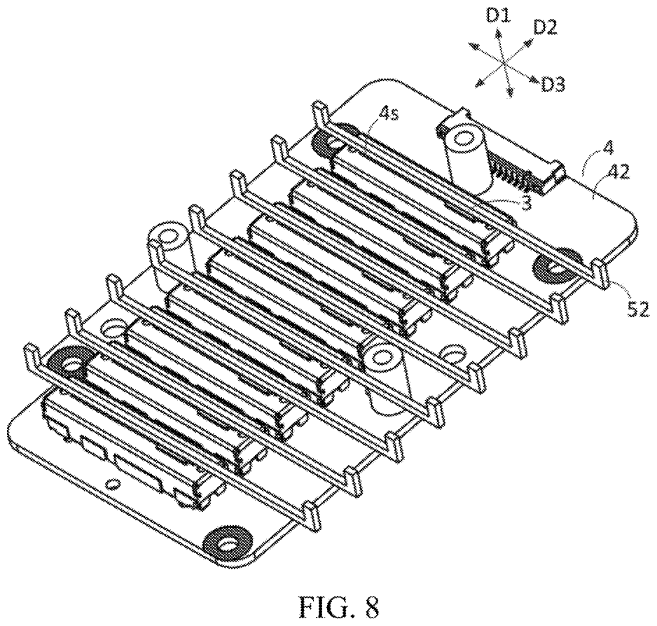

In this embodiment, the driven slider 3 may be made of, for example, rigid plastic. As shown in FIG. 3, FIG. 6, FIG. 7, and FIG. 8, a plurality of driven sliders 3 are all located at the second side D12 of the separator 1, and these driven sliders 3 are arranged side by side and spaced apart from each other in the first direction D1. Each driven slider 3 is disposed corresponding to one driving slider 2. Specifically, each driven slider 3 has a transmission coupling with one driving slider 2 via the transmission assembly 5, so that one driven slider 3 and one driving slider 2 are arranged in a pair. Therefore, when the driving slider 2 slides in a reciprocating manner along the third direction D3, the driving slider 2 can drive the driven slider 3 to slide in a reciprocating manner along the third direction D3, so that all the driving sliders 2 and all the driven sliders 3 reciprocate in parallel with each other. Moreover, each driven slider 3 also reciprocates in the range of the separation region 1r, that is, a sliding range of the driven slider 3 does not exceed the separation region 1r. In addition, the driven slider 3 can be mounted on a slide rail 4s formed by the circuit assembly 4, and the driven slider 3 can be limited by the slide rail 4s.

It may be understood that the present application limits neither a material nor a specific configuration of the driven slider 3. As long as the driven slider 3 can be in transmission coupling with the driving slider 2 and driven by the driving slider 2 to slide in a reciprocating manner in the range of the separation region 1r along the third direction D3, the driving slider 2 can adopt different materials and different configurations as required.

In this embodiment, as shown in FIG. 2 to FIG. 8, the circuit assembly 4 is located on the second side D12 of the separator 1. The circuit assembly 4 includes the electronic device 41 and a circuit board 42 that are assembled together. In addition, the circuit assembly 4 further has the slide rail 4s for mounting the driven slider 3. The electronic device 41 is mounted on the circuit board 42 and is located in the range of the separation region 1r. Thus, reciprocating sliding of the driven slider 3 can cause a change in an electrical characteristic of the electronic device 41. In an optional solution, the electronic device 41 includes a sliding rheostat, and the driven slider 3 adjusts a resistance value by means of changing a length or an area of a resistance wire. Specifically, the driven slider 3 is connected to the resistance wire. During reciprocating sliding of the driven slider 3, the length or the contact area of the resistance wire is changed, thereby changing the resistance value. The resistance value can be continuously changed through reciprocating sliding of the driven slider 3, to adjust the resistance. In another optional solution, the electronic device 41 includes a variable capacitor, and the driven slider 3 can adjust a capacitance value. Specifically, the driven slider 3 may be located between two parallel metal plates, and an effective distance between the metal plates is changed through reciprocating of the driven slider 3, thereby adjusting the capacitance value. A magnitude of the capacitance is inversely proportional to the distance between the two plates. Therefore, the capacitance value can be effectively changed by means of reciprocating of the driven slider 3. It can thus be seen that the electrical characteristic is one of resistance or capacitance. In another optional solution, the electrical characteristic may alternatively be both resistance and capacitance.

Further, as shown in FIG. 2, FIG. 3, FIG. 5, and FIG. 6, the circuit board 42 is provided with a plurality of mounting columns standing upright toward the separator 1, and each mounting column may be formed with a threaded hole. The partition portion 11 of the separator 1 is formed with a plurality of mounting holes in a region other than the separation region 1r, and each mounting hole corresponds to one mounting column. With a threaded connection member inserted into the threaded hole of the mounting column via the mounting hole, the circuit board 42 and the separator 1 are fastened to each other by means of a threaded fit between the threaded connection member and the threaded hole.

It may be understood that the present application does not limit a specific configuration of the circuit assembly 4, as long as the circuit assembly 4 can implement a required electrical function and can generate a corresponding change in the electrical characteristic during reciprocating sliding of the driven slider 3.

In this embodiment, as shown in FIG. 1 to FIG. 8, each transmission assembly 5 has a transmission coupling with a corresponding driving slider 2 and a corresponding driven slider 3, so that the driving slider 2 can drive, via the transmission assembly 5, the corresponding driven slider 3 to slide in a reciprocating manner in the range of the separation region 1r. Specifically, the transmission assembly 5 includes a first transmission member 51 and a second transmission member 52 corresponding to each other.

As shown in FIG. 3 and FIG. 4, each transmission assembly 5 includes two first transmission members 51 located at two sides of the driving slider 2, each first transmission member 51 includes an extension portion passing through the side wall portion 12 and extending out from an accommodating cavity surrounded by the top cover 6, the separator 1, and the sealing member 7, and each extension portion is opposite to a corresponding end portion of the second transmission member 52, so that the driving slider 2 abuts against the corresponding end portion of the second transmission member 52 via the extension portion to drive the driven slider 3. Further, in this embodiment, the first transmission member 51 is formed as a transmission rod extending linearly, the two first transmission members 51 are coaxially arranged, a first end portion 511 of the first transmission member 51 is inserted into the driving slider 2, and a second end portion 512 of the first transmission member 51 is configured as the extension portion. In addition, a body portion of the second transmission member 52 may be formed integrally with the driven slider 3 for fastening to each other. Two end portions of the second transmission member 52 tilt upward relative to the body portion of the second transmission member, so that the two end portions of the second transmission member 52 correspond to second end portions 512 of the two first transmission members 51, respectively. Moreover, there is a gap between at least one second end portion 512 and a corresponding end portion of the second transmission member 52. In this way, the first transmission member 51 is connected to the driving slider 2, the second transmission member 52 is connected to the driven slider 3, and the first transmission member 51 has a transmission coupling with the second transmission member 52 through the side wall portion 12. Because the transmission assembly 5 adopts the configuration described above, the first transmission member 51 is inserted into the driving slider 2, which facilitates assembly of the first transmission member 51 onto the driving slider 2. In addition, because there is a gap between the second end portion 512 used as the extension portion and the corresponding end portion of the second transmission member 52, the first transmission member 51 and the second transmission member 52 do not interfere with each other during assembly, which facilitates the assembly of the corresponding first transmission member 51 and second transmission member 52. In addition, the first transmission member 51 is disposed separate from the separator 1 in the range of the separation region 1r. In this way, even if a liquid flows to the separation region 1r, it is difficult for the liquid to flow out from the gap between the first transmission member 51 and the side wall portion 12 along the first transmission member 51.

It may be understood that the present application does not limit a specific configuration of the transmission assembly 5. The transmission assembly 5 may have various configurations as required as long as the transmission assembly 5 can implement transmission coupling between the driving slider 2 and the driven slider 3.

In this embodiment, the top cover 6 may be integrally formed using, for example, rigid plastic. As shown in FIG. 1 and FIG. 2, the top cover 6 is mutually fastened with the separator 1, and located at the first side D11 of the separator 1. A shape of the top cover 6 may be configured to adapt to a housing of a gain compensation control system adopting the electronic slide rail mechanism according to the present application, and therefore the top cover 6 may have various different structures and shapes as required. Further, the top cover 6 is formed with a slideway 6s corresponding to each driving slider 2, and the driving slider 2 is disposed on the corresponding slideway 6s and exposed from the top cover 6. In addition, the top cover 6 further abuts against the side wall portion 12 via the sealing member 7, so that the top cover 6, the separator 1, and the sealing member 7 surroundingly form an accommodating cavity at the separation region 1r, and the accommodating cavity can only communicate with the outside via the slideway 6s. In this way, after the electronic slide rail mechanism according to the present application is mounted in place, the liquid can only flow to a region between the top cover 6 and the separator 1 via the slideway 6s.

Further, as shown in FIG. 2 and FIG. 3, the top cover 6 is provided with a plurality of mounting columns standing upright toward the circuit board 42, and each mounting column may be formed with a threaded hole. The circuit board 42 of the circuit assembly 4 is formed with a plurality of mounting holes in a region other than the separation region 1r, and each mounting hole corresponds to one mounting column. With a threaded connection member inserted into the threaded hole of the mounting column via the mounting hole, the circuit board 42 and the top cover 6 are fastened to each other by means of a threaded fit between the threaded connection member and the threaded hole.

It may be understood that the present application limits neither a shape nor a structure of the top cover 6, and the top cover 6 may have various shapes and structures as required.

In this embodiment, the sealing member 7 may be made of, for example, an elastic material such as rubber. As shown in FIG. 2 to FIG. 10, a partial structure of the sealing member 7 is located between the top cover 6 and the separator 1, and a partial structure of the sealing member 7 is disposed between the first transmission member 51 and the side wall portion 12. Specifically, the sealing member 7 includes an annular body portion 72, and a plurality of sealing rings 71 protruding from the body portion 72 toward the side wall portion 12. A shape of the body portion 72 corresponds to a shape formed by all the side wall portions 12 as a whole, and the body portion 72 is located at an upper end portion of the side wall portion 12 and between the top cover 6 and the side wall portion 12, so that the body portion 72 of the sealing member 7 can implement sealing between the top cover 6 and the side wall portion 12. In addition, the side wall portion 12 is formed with a notch for the first transmission member 51 to pass through, and each sealing ring 71 is assembled in a corresponding notch. Thus, each sealing ring 71 is located between a part of the first transmission member 51 at the notch and the side wall portion 12, so that the sealing ring 71 of the sealing member 7 can implement sealing between the first transmission member 51 and the side wall portion 12. Even if a liquid flows into the separation region 1r, the sealing ring 71 can achieve a good sealing effect in a process in which the first transmission member 51 slides in a reciprocating manner with the driving slider 2 along the third direction D3.

According to the described solution, when the electronic slide rail mechanism is mounted in place, the accommodating cavity surrounded by the top cover 6, the separator 1, and the sealing member 7 communicates with the outside via only the slideway 6s of the top cover 6. Even if a liquid such as water or disinfectant flows into the accommodating cavity via the slideway 6s, the liquid is only collected in the accommodating cavity and located on the first side D11 of the separation region 1r, and does not flow to the second side D12 of the separation region 1r, that is, does not flow to a region in which the circuit assembly 4 is located. In this way, when the electronic slide rail mechanism is mounted in place, the slideway 6s of the top cover 6 and the circuit assembly 4 are completely spaced apart in space by using the separator 1, so that a failure of the circuit assembly 4 located on the second side D12 of the separator 1 can be completely avoided, and the electronic slide rail mechanism implements liquid-proof functionality with a relatively simple configuration. In addition, the top cover 6, the separator 1, and the circuit assembly 4 are detachably fastened to each other, so that not only can a modular configuration of the entire electronic slide rail mechanism be implemented, but also transportation and mounting are facilitated. Moreover, the electronic slide rail mechanism can be conveniently disassembled, thereby facilitating cleaning and maintenance of each component.

An electronic slide rail mechanism according to a third embodiment of the present application is described below.

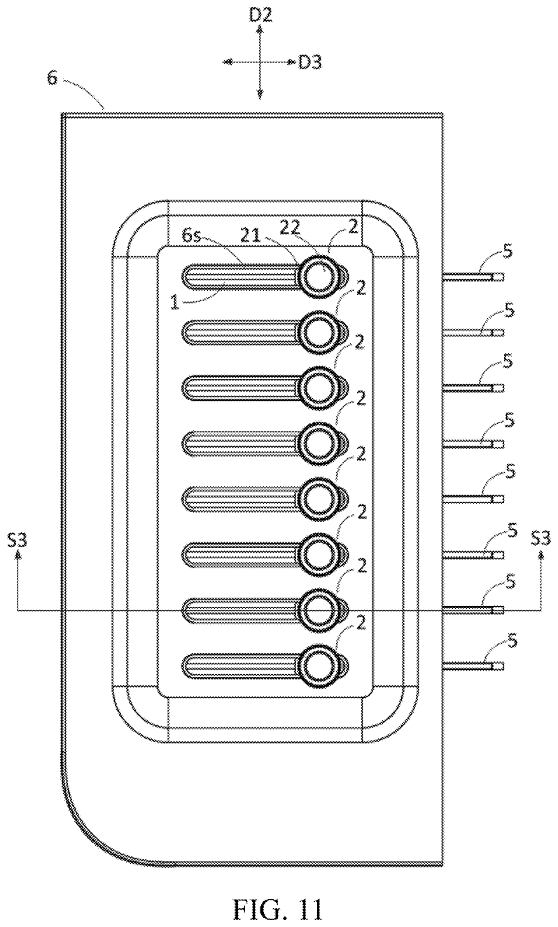

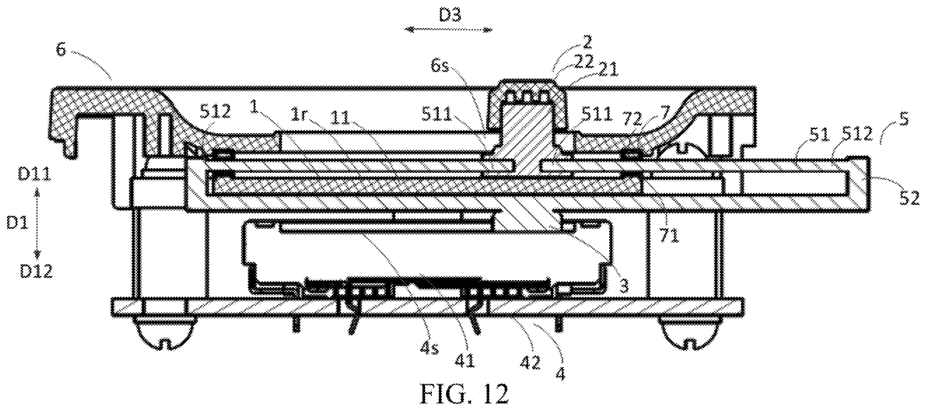

As shown in FIG. 11 and FIG. 12, a structure of the electronic slide rail mechanism according to the third embodiment of the present application is basically the same as that of the electronic slide rail mechanism according to the second embodiment of the present application, and the differences between the two are mainly described below.

In this embodiment, a structure of the transmission assembly 5 is different from that of the transmission assembly 5 in the second embodiment. Specifically, as shown in FIG. 11 and FIG. 12, the first transmission member 51 of the transmission assembly 5 is formed as a transmission rod extending linearly, and the two first transmission members 51 are coaxially arranged. The first end portion 511 of the first transmission member 51 is inserted into the driving slider 2, and the second end portion 512 of the first transmission member 51 is formed as the extension portion. The second end portion 512 used as the extension portion and the second transmission member 52 may be fixedly connected together by means of welding, bonding, or the like. In this way, in a state in which the driven slider 3 is mounted on the slide rail 4s of the circuit assembly 4, the driven slider 3 can reciprocate on the slide rail 4s by using the transmission assembly 5, so as to cause a change in the electrical characteristic of the electronic device 41.

In addition, in a variant example of this embodiment, the second transmission member 52 may alternatively be formed integrally with the first transmission member 51. For example, only one first transmission member 51 is provided, and the first transmission member 51 and the second transmission member 52 are integrally formed as a whole.

In this embodiment and the variant example thereof, not only is an optional solution of the transmission assembly 5 proposed, enabling the electronic slide rail mechanism to be adapted to more application scenarios, but another structure of the electronic slide rail mechanism is the same as a corresponding structure of the electronic slide rail mechanism according to the second embodiment, so that the same effects as those described in the second embodiment can be achieved.

An electronic slide rail mechanism according to a fourth embodiment of the present application is described below.

A structure of the electronic slide rail mechanism according to the fourth embodiment of the present application is basically the same as that of the electronic slide rail mechanism according to the second embodiment of the present application, and the differences between the two are mainly described below.

In this embodiment, a structure of the transmission assembly 5 is different from that of the transmission assembly 5 in the second embodiment. Specifically, the first transmission member 51 and the second transmission member 52 are each a flexible connection member. The paired first transmission member 51 and second transmission member 52 are directly connected to each other to form a transmission connection member, and two side portions of the driving slider 2 are connected to two side portions of the driven slider 3, respectively, by means of two transmission connection members. The electronic slide rail mechanism further includes a pulley. The pulley may be directly fastened to the separator 1, or may be fastened to another component to be fixed relative to the separator 1. Each transmission connection member is wound around a corresponding pulley and is tensioned and supported by the pulley. In this way, in a state in which the driven slider 3 is mounted on the slide rail 4s of the circuit assembly 4, the driven slider 3 can reciprocate on the slide rail 4s by using the transmission assembly 5, so as to cause a change in the electrical characteristic of the electronic device 41.

In this embodiment, not only is another optional solution of the transmission assembly 5 proposed, enabling the electronic slide rail mechanism to be adapted to more application scenarios, but another structure of the electronic slide rail mechanism is the same as a corresponding structure of the electronic slide rail mechanism according to the second embodiment, so that the same effects as those described in the second embodiment can be achieved.

In addition, the present application further provides a gain compensation control system, and the gain compensation control system is used in an ultrasonic imaging apparatus. Further, the gain compensation control system includes the electronic slide rail mechanism according to any embodiment described above. The gain compensation control system is a time gain compensation control system or a lateral gain compensation control system. Specifically, the electronic slide rail mechanism can be adaptively assembled with other components such as a housing of the gain compensation control system.

The present application further provides an ultrasonic imaging apparatus including the gain compensation control system described above. The foregoing solution provides a typical application scenario of the gain compensation control system according to the present application. It may be understood that the gain compensation control system according to the present application can also be used in other application scenarios.

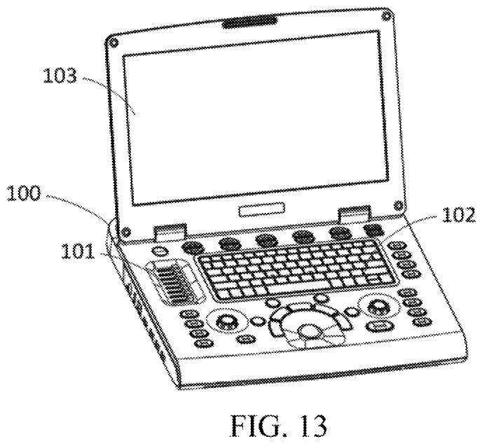

The ultrasonic imaging apparatus according to the embodiment of the present application may include an ultrasonic probe, an ultrasonic transceiver module, and an operation module (see FIG. 13).

The ultrasonic probe may be various types of probes, including but not limited to a linear probe, a curved array probe, and an array probe. The ultrasonic transceiver module may include a transmission beamformer, a transmitter, a receiver, and a reception beamformer. Both the transmission beamformer and the transmitter drive the ultrasonic probe to transmit a pulsed ultrasonic signal into a body of an object (for example, a human body) to be imaged. The pulsed ultrasonic signal is backscattered from a structure in the body of the object to be imaged, generating an echo. The echo is converted into an electrical signal, and the electrical signal is received by the receiver and passes through the reception beamformer that outputs ultrasonic data. In different solutions, some or all of the transmission beamformer, the transmitter, the receiver, and the reception beamformer may be located in the ultrasonic probe, so as to execute some or all work of transmission beamforming and/or reception beamforming.

The operation module may be used to control work of the ultrasonic imaging apparatus; for example, the module may be used to control data input, select a working mode, adjust a related parameter, and the like. Specifically, as shown in FIG. 13, the operation module may include a host 100, a gain compensation control system 101, an input component 102, a processor, a memory and a display 103, which are integrated together.

A housing of the host 100 may be made of a rigid material, so as to support and protect other components. As shown in FIG. 13, the gain compensation control system 101 and the input component 102 are disposed in the host 100 and exposed from the housing to the outside for easy operation by a user. The gain compensation control system 101 includes the electronic slide rail mechanism according to the present application that is specifically described in the foregoing specific embodiments, and a partial structure of the electronic slide rail mechanism including the driving slider 2 is exposed from the host 100. The input component 102 may be a keyboard, a hard key, a touch pad, a touchscreen, a trackball, a rotary control, a slider, a soft key, or any other user input apparatus, and the input component 102 is used by the user to interact with the operation module.

Both the processor and the memory are disposed in the host 100, and are protected by the housing. The processor may control the transmission beamformer, the transmitter, the receiver, and the reception beamformer. The processor has a communication connection with the ultrasonic probe, so as to control the ultrasonic probe to collect ultrasonic data and a shape of a beam emitted from the ultrasonic probe. The processor further has a communication connection with the display 103, so as to process the ultrasonic data into an image (for example, a 2D image or a 3D image) for display on the display 103. The “communication connection” may include a wired connection and a wireless connection. In a typical example, in addition to a central processing unit, the processor may further include other electronic components capable of performing a processing function, for example, a digital signal processor, a field-programmable gate array, a graphics processing unit, or any other type of electronic component. The ultrasonic imaging apparatus may include a plurality of processors, so as to have a sufficient processing capability to cope with processing tasks. It may be understood that other embodiments may adopt processors of different types, numbers, and arrangements as required. In addition, if the reception beamformer is a software beamformer, a processing task of the software beamformer may alternatively be performed by the processor. In addition, the memory may include various types of storage units and have sufficiently large storage space for storing various data. The memory may include any known data storage medium.

As shown in FIG. 13, the display 103 is connected to the host 100 in a manner so as to be capable of freely rotating relative to the host 100. Thus, the display 103 can be located at various positions relative to the host 100 as required. The display 103 may be various types of display apparatuses, and is used to display an image.

In another optional solution, the ultrasonic imaging apparatus according to the embodiment of the present application may include various other components as required, which are not enumerated or described in detail herein. In addition, FIG. 13 shows a portable ultrasonic imaging apparatus, and the embodiments of the present application are also applicable to other types of ultrasonic imaging apparatuses.

It should be understood that the above embodiments are only exemplary and are not intended to limit the present application. Those skilled in the art may make various modifications and changes to the above embodiments under the teachings of the present disclosure, without departing from the scope of the present application. The technical solutions of the present application are supplementarily described as follows.
i. In the description of the foregoing embodiments, the separation region 1r of the separator 1 is defined by providing the side wall portion 12 on the partition portion 11, but the present application is not limited thereto, and the separation region 1r of the separator 1 may alternatively be defined without using the side wall portion 12 in conjunction with the partition portion 11.

For example, in a variant example of the foregoing embodiment, the side wall portion 12 may not be provided. In such a case, if the entire partition portion 11 is not formed with a passage such as a through hole that places two sides of the separator 1 in communication, the entire partition portion 11 defines the separation region 1r.
ii. In the foregoing embodiments, different embodiments of the transmission assembly 5 are described, but the present application is not limited thereto. It may be understood that, as long as there is no impact on a case that the two sides of the separator 1 are completely separated in the separation region 1r, the transmission assembly 5 may adopt various different structures according to different situations, and is not limited to the structure of the transmission assembly 5 described in the foregoing embodiments.

The exemplary embodiments and variants of the present application have been described above; however, it should be understood that various modifications may be made. For example, same, similar, or other suitable results can be achieved if the described techniques are executed in a different order and/or if components in the described systems, architectures, devices, or circuits are combined in different ways and/or replaced or supplemented by additional components or equivalents thereof; and these changes or modifications also fall within the scope of protection of the claims.

1. An electronic slide rail mechanism, comprising:
a separator, defining a separation region, a first side and a second side of the separator being completely separated in a range of the separation region;
a driving slider, located at the first side of the separator, the driving slider being capable of reciprocating within the range of the separation region;
a driven slider, located at the second side of the separator and disposed corresponding to the driving slider;
a transmission assembly having a transmission coupling with the driving slider and the driven slider, wherein the driving slider is configured to drive, via the transmission assembly, the corresponding driven slider to reciprocate in the range of the separation region; and
a circuit assembly, located at the second side of the separator, the circuit assembly comprising an electronic device, the electronic device being located in the range of the separation region, wherein movement of the driven slider is configured to cause a change in an electrical characteristic of the electronic device.

2. The electronic slide rail mechanism according to claim 1, wherein the separator comprises a partition portion and a side wall portion, and the side wall portion extends from the partition portion toward the first side, so that the partition portion and the side wall portion surroundingly form the separation region.

3. The electronic slide rail mechanism according to claim 2, further comprising a top cover and a sealing member,
the top cover being mutually fastened with the separator and located at the first side of the separator, the top cover being formed with a slideway corresponding to the driving slider, and the driving slider being disposed in the corresponding slideway and exposed from the top cover, and
the top cover abutting against the side wall portion via the sealing member, so that an accommodating cavity is formed at the separation region, and the accommodating cavity is only configured to communicate with an outside via the slideway.

4. The electronic slide rail mechanism according to claim 2, wherein the transmission assembly comprises a first transmission member and a second transmission member, the first transmission member is connected to the driving slider, the second transmission member is connected to the driven slider, and the first transmission member has a transmission coupling with the second transmission member through the side wall portion.

5. The electronic slide rail mechanism according to claim 4, further comprising a sealing member, the sealing member being disposed between the first transmission member and the side wall portion.

6. The electronic slide rail mechanism according to claim 4, wherein the first transmission member is disposed separated from the separator in the range of the separation region.

7. The electronic slide rail mechanism according to claim 4, wherein the first transmission member comprises an extension portion passing through the side wall portion, and the extension portion is fixedly connected to the second transmission member.

8. The electronic slide rail mechanism according to claim 4, wherein each transmission assembly comprises two first transmission members located at two sides of the driving slider, each first transmission member comprises an extension portion passing through the side wall portion, and each extension portion is opposite to a corresponding end portion of the second transmission member, so that the driving slider abuts against the corresponding end portion of the second transmission member via the extension portion, to drive the driven slider.

9. The electronic slide rail mechanism according to claim 8, wherein the first transmission member is configured as a transmission rod extending linearly, the two first transmission members are coaxially arranged,
a first end portion of the first transmission member is inserted into the driving slider, a second end portion of the first transmission member is formed as the extension portion, and there is a gap between at least one extension portion and a corresponding end portion of the second transmission member.

10. The electronic slide rail mechanism according to claim 4, wherein the first transmission member and the second transmission member are each a flexible connection member, the first transmission member and second transmission member are directly connected to each other to form a transmission connection member, and two side portions of the driving slider are connected to two side portions of the driven slider, respectively, by means of two transmission connection members,
the electronic slide rail mechanism further comprises a pulley, the pulley is fixed relative to the separator, and each transmission connection member is wound around a corresponding pulley and is tensioned and supported by the pulley.

11. The electronic slide rail mechanism according to claim 1, wherein the circuit assembly has a slide rail, and the driven slider is mounted on the slide rail, so that the driven slider is configured to reciprocate on the slide rail to cause a change in an electrical characteristic of the electronic device.

12. The electronic slide rail mechanism according to claim 11, wherein the electrical characteristic comprises resistance or capacitance.

13. The electronic slide rail mechanism according to claim 11, wherein the circuit assembly further comprises a circuit board, the electronic device is mounted on the circuit board, and the circuit board and the separator are fastened to each other.

14. The electronic slide rail mechanism according to claim 1, comprising a plurality of driving sliders arranged separate from each other and a plurality of driven sliders arranged separate from each other, one driving slider having a corresponding transmission coupling with one driven slider, and all the driving sliders and all the driven sliders reciprocating in parallel with each other.

15. A gain compensation control system, comprising:
a separator, defining a separation region, a first side and a second side of the separator being completely separated in a range of the separation region;
a driving slider, located at the first side of the separator, the driving slider being capable of reciprocating within the range of the separation region;
a driven slider, located at the second side of the separator and disposed corresponding to the driving slider; and
a transmission assembly having a transmission coupling with the driving slider and the driven slider, wherein the driving slider is configured to drive, via the transmission assembly, the corresponding driven slider to reciprocate in the range of the separation region; and
a circuit assembly, located at the second side of the separator, the circuit assembly comprising an electronic device, the electronic device being located in the range of the separation region, wherein movement of the driven slider is configured to cause a change in an electrical characteristic of the electronic device.

16. The gain compensation control system according to claim 15, wherein the gain compensation control system is a time gain compensation control system or a lateral gain compensation control system.

17. An ultrasonic imaging apparatus, comprising a gain compensation control system, the gain compensation control system comprising:
a separator, defining a separation region, a first side and a second side of the separator being completely separated in a range of the separation region;
a driving slider, located at the first side of the separator, the driving slider being capable of reciprocating within the range of the separation region;
a driven slider, located at the second side of the separator and disposed corresponding to the driving slider; and
a transmission assembly having a transmission coupling with the driving slider and the driven slider, wherein the driving slider is configured to drive, via the transmission assembly, the corresponding driven slider to reciprocate in the range of the separation region; and
a circuit assembly, located at the second side of the separator, the circuit assembly comprising an electronic device, the electronic device being located in the range of the separation region, wherein movement of the driven slider is configured to cause a change in an electrical characteristic of the electronic device.
